(19) United States
(12) Patent Application Publication
(10) Pub. No.: US 2009/0194152 A1
(43) Pub. Date: Aug. 6, 2009

(54) THIN-FILM SOLAR CELL HAVING HETERO-JUNCTION OF SEMICONDUCTOR AND METHOD FOR FABRICATING THE SAME

(75) Inventors: Chee-Wee Liu, Taipei (TW); Cheng-Yeh Yu, Taipei (TW); Wen-Yuan Chen, Taipei (TW); Chu-Hsuan Lin, Taipei (TW)

Correspondence Address: VOLPE AND KOENIG, P.C., UNITED PLAZA, SUITE 1600, 30 SOUTH 17TH STREET, PHILADELPHIA, PA, 19103, US

(73) Assignee: NATIONAL TAIWAN UNIVERSITY, Taipei (TW)

(21) Appl. No.: 12/025,226

(22) Filed: Feb. 4, 2008

(51) Int. Cl. H01L 31/0336; H01L 31/18

(52) U.S. Cl. 136/255; 438/94; 257/E31.005

(57) ABSTRACT

A thin-film solar cell having a hetero-junction of semiconductor and the fabrication method thereof are provided. Instead of the conventional hetero-junction of III-V semiconductor or homo-structure of IV semiconductor, the thin-film solar cell according to the present invention adopts a novel hetero-junction structure of IV semiconductor to improve the cell efficiency thereof. By adjusting the amount of layer sequences and the thickness of the hetero-junction structure, the cell efficiency of the thin-film solar cell according to the present invention is also optimized.

### FIELD OF THE INVENTION

The present invention relates to a thin film solar cell and the fabrication method therefor, and more particularly to a thin-film solar cell having hetero-junction of semiconductor and the method for fabricating the same.

### BACKGROUND OF THE INVENTION

Most of the solar cells according to the prior art are usually constructed by forming therein a hetero-junction structure made of the III-V semiconductor materials or a homo-junction structure made of the IV group semiconductor materials. As the solar cells hold much promise for the alternative power system, the relevant technologies for fabricating the solar cell are also well developed.

For example, in the U.S. Pat. No. 5,374,564, a method for forming a homo-junction of IV group semiconductor materials by using a thin film transfer technology is provided. The method has also been well known as the “smart-cut” process. Further, in the U.S. Pat. No. 7,019,339, a method for fabricating a solar cell constructed by a Ge-based hetero-structure having therein a hetero-junction of III-V semiconductor materials is provided. The Ge-based hetero-structure is formed by the smart cut process, i.e. transferring a germanium layer into a non-germanium substrate.

Nevertheless, it is disadvantageous that the solar cell made of the III-V semiconductor materials and the Ge-based hetero-structure is costly. Further, it is well known that the exfoliated surface of the germanium film is full of defects since such surface is formed by the exfoliation of the implanted hydrogen ions (H⁺), so that the power conversion efficiency of the solar cell will be greatly reduced. Although such defects on the exfoliated surface of the germanium film might be removed by the etching process or the chemical-mechanical polishing (CMP) process, such additional processes still cause a further process cost and the waste of the removed germanium.

On the other hand, although it is disclosed in the U.S. Pat. No. 6,670,544 that a solar cell structure is made of the silicon and germanium materials, it is clear that such structure cannot be formed on the glass substrate as a form of film. Therefore, the fabrication cost for such solar cell structure made of the silicon and germanium materials still cannot be remarkably reduced.

In order to overcome the above-mentioned issues, a novel thin-film solar cell having hetero-junction of semiconductor and the method for fabricating the same are provided. In such a solar structure and the fabrication method, the manufacturing process of the thin-film solar cell having the hetero-junctions of silicon-germanium-silicon is much simpler, and the necessary materials and its relevant fabrication cost for such thin-film solar cell structure are remarkably reduced.

### SUMMARY OF THE INVENTION

In accordance with an aspect of the present invention, a thin-film solar cell is provided. The thin-film solar cell includes a substrate having a first surface, a multi-layered structure disposed on the first surface, a first electrode layer disposed on the multi-layered structure, an insulation layer, and a second electrode layer disposed on the insulation layer and insulated from the first electrode layer, wherein the first electrode layer is a ring shaped structure having a vacant space formed thereon

Preferably, the multi-layered structure is made of different semiconductor materials selected from elements of the same group.

Preferably, the substrate is one selected from a group consisting of a relatively low quality silicon substrate, a glass substrate and a relatively cheap substrate.

Preferably, the multi-layered structure is made of the different semiconductor materials of IV group elements.

Preferably, the multi-layered structure further includes a first silicon layer, a hetero-structure layer disposed on the first silicon layer, and a second silicon layer disposed on the hetero-structure layer, wherein the hetero-structure layer is one of a germanium layer and a silicon-germanium layer.

Preferably, the hetero-structure layer has a thickness ranged from 3 nm to 30 nm.

Preferably, the multi-layered structure one of a Si/Ge/Si quantum well and a Si/Ge/Si quantum dot.

Preferably, the multi-layered structure one of a Si/SiGe/Si quantum well and a Si/SiGe/Si quantum dot.

Preferably, the insulation layer is made of a dielectric material having a dielectric constant lager than 3.

Preferably, the dielectric material is one of a group consisting of a silicon dioxide, a silicon nitride, and a hafnium oxide.

In accordance with a further aspect of the present invention, a thin-film solar cell is provided. The thin-film solar cell includes a substrate having a first surface, a first electrode layer disposed on the first surface, a multi-layered structure disposed on the first electrode layer, and an insulation layer disposed on the multi-layered structure, wherein the multi-layered structure has a hetero junction structure formed by different semiconductor materials selected from elements of the same group.

In accordance with a further aspect of the present invention, a method for fabricating a thin-film solar cell is provided, wherein the thin-film solar cell having a hetero-junction structure formed by different semiconductor materials selected from elements of the same group. The method includes the following step: (a) providing a silicon substrate having a first surface and a second surface; (b) providing a semiconductor layer made of IV group elements on the first surface; (c) providing a silicon layer on the semiconductor layer, so as to form a hetero-junction structure; (d) implanting hydrogen ions (H⁺) into the hetero-junction structure, so that an implanted hydrogen ions interface is formed within the silicon substrate; and (e) providing a carrier substrate bonding to the silicon layer and heating the hetero-junction structure having the implanted hydrogen ions interface, so that the silicon substrate is exfoliated along the hydrogen ions interface and a exfoliated surface of the silicon substrate is formed.

Preferably, the method further includes a step of (e′) doping the hetero-junction structure after the step (e).

Preferably, the method further includes a step of (e″) planarizing the exfoliated surface after the step (e).

Preferably, the method further includes following steps after the step (e″): (f) providing a first electrode layer on the exfoliated surface; (g) forming a vacant space on the central portion of first electrode layer, so as to make the first electrode as a ring shaped structure, wherein an exposed portion of the exfoliated surface is revealed in the vacant space (h) providing an insulation layer on the exposed portion of the exfoliated surface; and (i) providing a second electrode layer on the insulation layer, through which the first electrode layer is insulated from the second electrode layer.

Preferably, the step (e) further includes steps of (e1) providing the carrier substrate having thereon a first electrode layer, and (e2) bonding the first electrode layer into the silicon layer.

Preferably, the method further includes a step of (f) providing a second electrode layer on the exfoliated surface after the step (e).

Preferably, the semiconductor layer and the silicon layer are formed by one of an epitaxial process and a wafer bonding process.

Preferably, the epitaxial process is performed by one selected from a group consisting of a molecular beam epitaxy (MBE) system, a plasma enhanced chemical vapor deposition (PECVD) system, and an ultra high vacuum chemical vapor deposition (UHVCVD) system.

Preferably, the step (b) and the step (c) are alternately and repeatedly performed, so that a multi-layered structure having multiple hetero-junctions is formed.

### BRIEF DESCRIPTION OF THE DRAWINGS

The above objects and advantages of the present invention will become more readily apparent to those ordinarily skilled in the art after reviewing the following detailed descriptions and accompanying drawings, in which:

FIGS. 1(A) to 1(H) are diagrams schematically showing the structure and the manufacturing process of the thin film solar cell according to a first embodiment of the present invention;

FIGS. 2(A) to 2(C) are diagrams schematically showing the structure and the manufacturing process of the thin film solar cell according to a second embodiment of the present invention.

FIGS. 3(A) and 3(B) are diagrams respectively showing the alternative structures of the thin film solar cell according to the first and second embodiments of the present invention;

FIG. 4 is a diagram showing that the number of the germanium layers contained in the thin-film solar cell of the present invention is effective to the power efficiency of the solar cell;

FIG. 5 is a diagram showing the voltage-current characteristic of the solar cell having three germanium layers;

FIG. 6 is a diagram showing that the thickness of the germanium layer contained in the solar cell of the present invention is effective to the power efficiency of the solar cell; and

FIG. 7 is a diagram showing the voltage-current characteristic of the solar cell including a germanium layer having a thickness of 30 nm.

### DETAILED DESCRIPTION OF THE PREFERRED EMBODIMENT

The present invention will now be described more specifically with reference to the following embodiments. It should be noted that the following descriptions of preferred embodiments of this invention are presented herein for purposes of illustration and description only; it is not intended to be exhaustive or to be limited to the precise form disclosed.

In the present invention, a thin-film solar cell having a hetero-junction structure of IV group semiconductor materials is provided. In comparison with the conventional solar cell, the thin-film solar cell of the present invention has a better power conversion efficiency than what the conventional solar cell has.

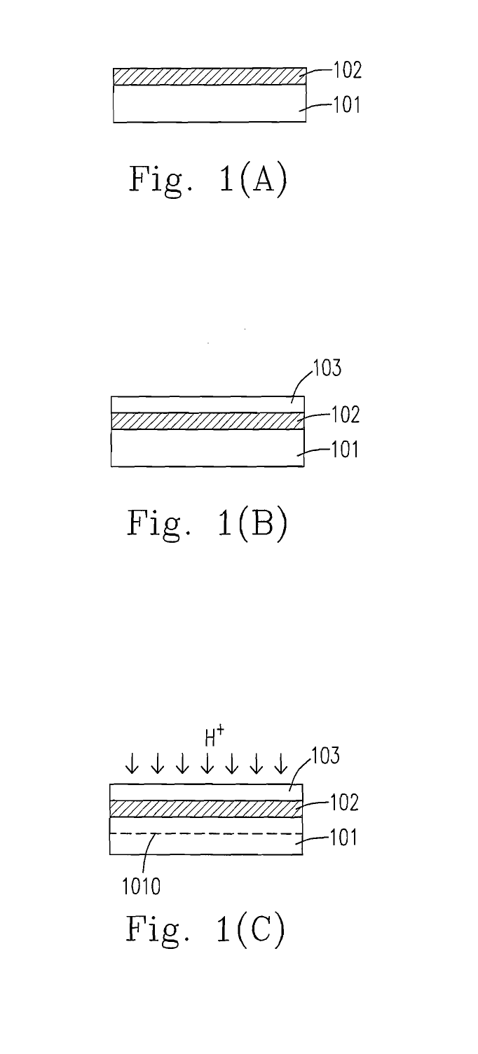

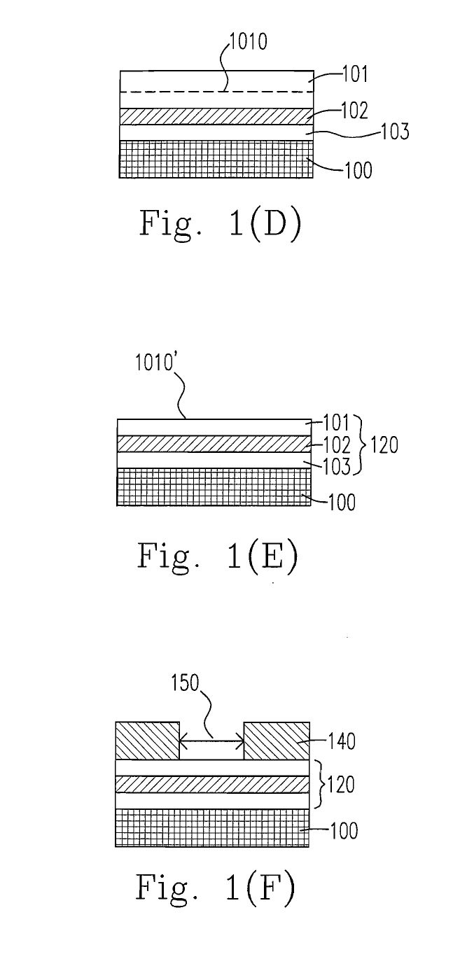

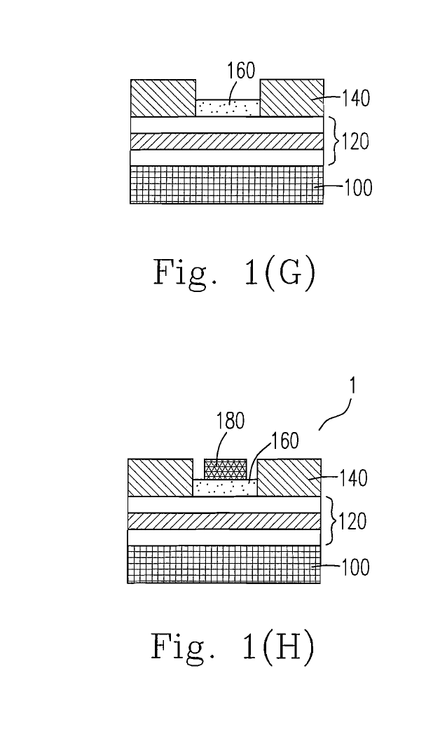

Please refer to FIG. 1(A) to FIG. 1(H), which respectively show the schematic structure and the manufacturing process of the thin film solar cell according to a first embodiment of the present invention.

As shown in FIG. 1(A), a silicon substrate 101 having a germanium layer 102 disposed on a first surface thereof is provided. The germanium layer 102 is formed on the silicon substrate 101 through an epitaxial process preformed by one selected from a group consisting of a molecular beam epitaxy (MBE) system, a plasma enhanced chemical vapor deposition (PECVD) system, and an ultra high vacuum chemical vapor deposition (UHVCVD) system, or through a wafer bonding process. Further, as shown in FIG. 1(B), a silicon layer 103 is disposed on the germanium layer 102. Similarly, the silicon layer 103 can be formed by one of the epitaxial process and the wafer bonding process. After forming the germanium layer 102 and the silicon layer 103 on the silicon substrate 101, a hetero-junction structure made of the different IV group semiconductor materials is formed.

Please further refer to FIG. 1(C), after forming the hetero-junction structure, a hydrogen ions (H⁺) implantation process is applied to the hetero-junction structure, so that an implanted hydrogen ions interface 1010 is formed within the silicon substrate 101. Furthermore, in order to employ such hetero-junction structure as a key component of the thin film solar cell of the present invention, a carrier substrate 100 bonding to the silicon layer 103 is provided for mounting the hetero-junction structure, as shown in FIG. 1(D). Then, as shown in FIG. 1(E), after bonding the carrier substrate 100 to the silicon layer 103, the hetero-junction structure 120 is processed by a heat treatment in a relatively high temperature, and part of the silicon substrate 101 of the hetero-junction structure 120 is exfoliated along the hydrogen ions interface 1010, so that an exfoliated surface 1010′ of the silicon substrate 101 is formed.

Generally, the removed part of the silicon substrate 101 can be reused as the silicon material for another hetero-junction structure. Further, on the other hand, in order to prevent the fabricated hetero-junction structure 120 from being affected by the roughness of the exfoliated surface 1010′, a planarization process, such as the known chemical mechanic polish (CMP) process, is implemented on the exfoliated surface 1010′. After planarizing the exfoliated surface 1010′, a first electrode layer 140 is disposed on the exfoliated surface 1010′, wherein the first electrode layer 140 is a ring shape structure having a vacant space 150 formed thereinside, as shown in FIG. 1(F), so that an exposed portion of the exfoliated surface 1010′ is formed in the vacant space. Then, an insulation layer 160 is formed on the exposed portion of the exfoliated surface 1010′, as shown in the respective FIG. 1(G), and a second electrode layer 180 is formed on the insulation layer 160, so that the second electrode layer 180 can be insulated from the first electrode layer 140, shown in FIG. 1(H). Accordingly, as shown in FIG. 1(H), a thin film solar cell 1 having a hetero-junction structure made by IV group semiconductor materials according to the first embodiment of the present invention is provided.

Specifically, the abovementioned hetero-junction structure 120 is a Si/Ge/Si multi-layered structure. Further, in a preferred embodiment of the present invention, the hetero-junction structure 120 also can be formed by a Si/Ge/Si quantum dot or quantum well, or can be formed by a Si/SiGe/Si quantum dot or quantum well.

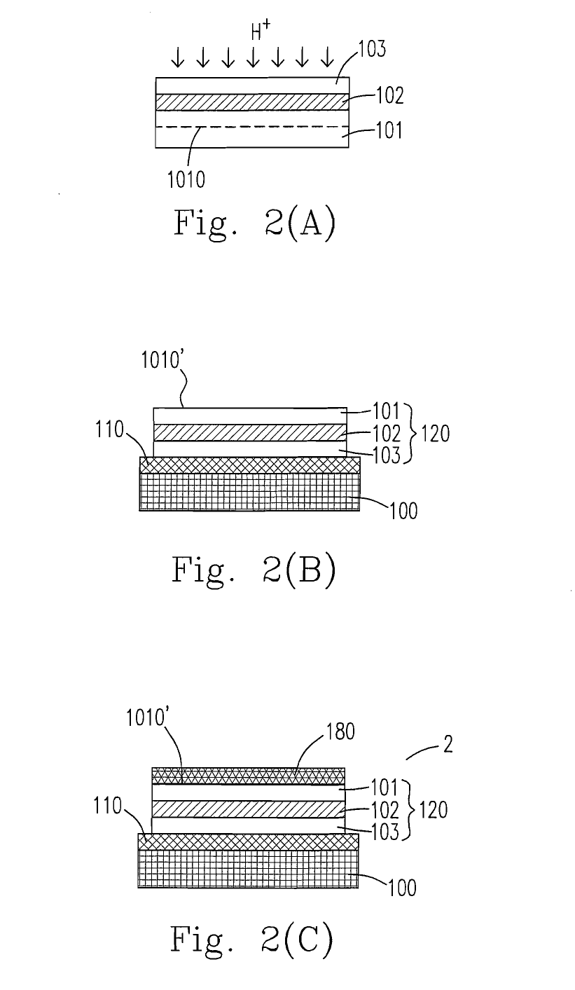

Please further refer to FIG. 2(A) to FIG. 2(C), which respectively show the schematic structure and the manufacturing process of the thin film solar cell according to a second embodiment of the present invention. As shown in FIG. 2(A), the thin film solar cell according to the second embodiment of the present invention also include a hetero-junction structure 120 formed by a silicon substrate 101, a germanium layer 102 and a silicon layer 103. Further, as also shown in FIG. 2(A), the hetero-junction structure 120 is also implanted by the hydrogen ions, so that an implanted hydrogen ions interface 1010 is formed within the silicon substrate.

Further, as shown in FIG. 2(B), the main difference between the thin-film solar cells of the first embodiment and the second embodiment is that the hetero-junction structure 120 is bonded to a carrier substrate 100 having a first electrode layer 110 formed thereon, so that the first electrode layer 110 of the thin-film solar cell according to the second embodiment of the present invention is disposed between the silicon layer 103 of the hetero-junction structure 120 and the carrier substrate 100. Similarly, after bonding the carrier substrate 100 having the first electrode layer 110 to the silicon layer 103 of the hetero-junction structure 120, a heat treatment and a planarization process is subsequently employed, so that an exfoliated surface 1010′ of the silicon substrate 101 is formed. Then, as shown in FIG. 2(C), a second electrode layer 180 is directly formed on the exfoliated surface 1010′ without the interfacing of the insulation layer, and a thin-film solar cell 2 according the second embodiment of the present invention is formed.

In a preferred embodiment of the present invention, the thin-film solar cell 2 shown in FIG. 2(C) could be used as one of the Metal Oxide Semiconductor (MOS) type solar cell and P-type/intrinsic/N-type (PIN) type solar cell. Moreover, the carrier substrate 100 and the first electrode layer 110 of the thin-film solar cell 2 according the second embodiment of the present invention could be selected from a non-opaque material, so that the sunlight can enter into the thin-film solar cell from the side of the carrier substrate 100, in order to prevent the incident sunlight from being blocked by the second electrode layer 180.

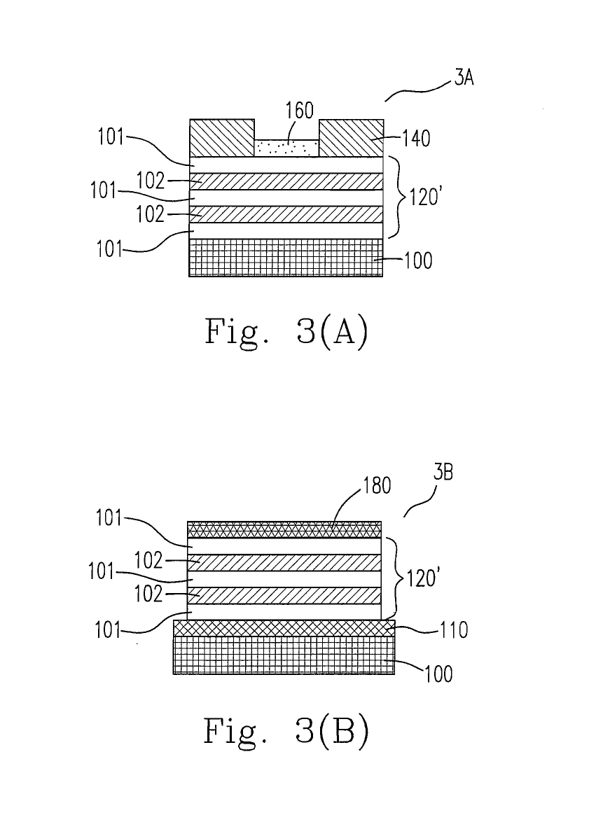

Please refer to FIGS. 3(A) and 3(B), which respectively show the alternative structures of the solar cell according to the first and the second embodiments of the present invention. As shown in FIG. 3(A), the main difference between the thin film solar cell 3A and the abovementioned solar cell 1 shown in FIG. 1(H) is that the hetero-junction structure 120′ thereof is formed by multiple silicon layers 101 and multiple germanium layers 102 alternately stacked to one another. Similarly, as shown in FIG. 3(B), the main difference between the thin film solar cell 3B and the abovementioned solar cell 2 shown in FIG. 2(C) is that the hetero-junction structure 120′ thereof is also formed by multiple silicon layers 101 and multiple germanium layers 102 alternately stacked to one another. Moreover, it should be noted that the multi-layered hetero-junction structure 120′ of the solar cell of the present invention could also be replaced by a stacked structure formed by multiple silicon germanium (SiGe) layers and multiple germanium layers.

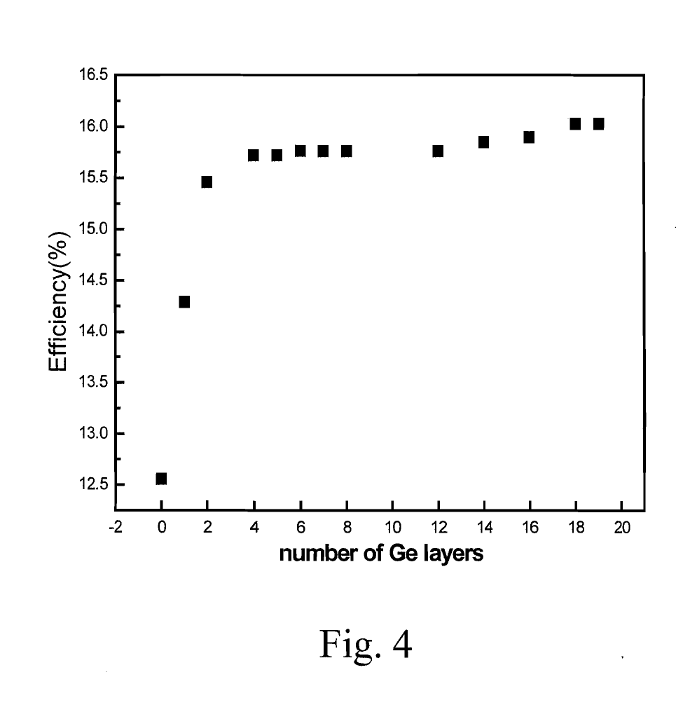

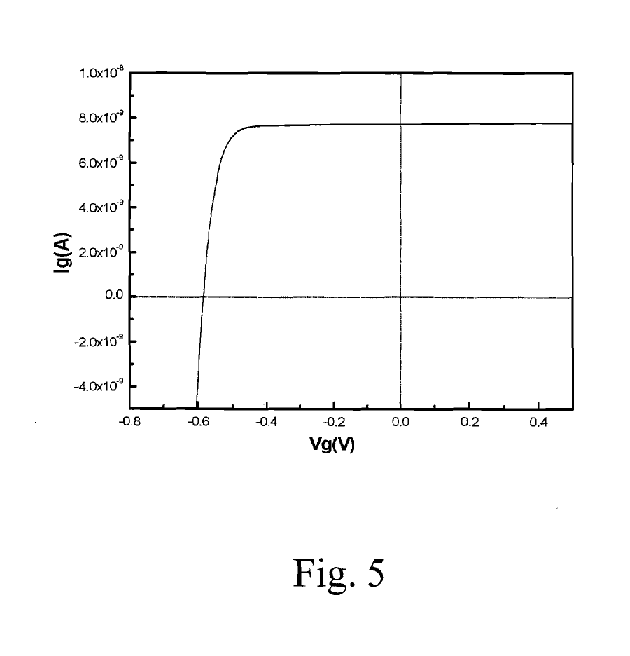

On the other hand, in a preferred embodiment of the present invention, the number of the germanium layer contained in the thin-film solar cell can be used as a parameter to enhance the power efficiency of the thin-film solar cell. Please refer to FIG. 4, which shows a diagram indicating that the number of the germanium layer contained in the thin-film solar cell of the present invention is effective to the power efficiency of the solar cell. From the data shown in FIG. 4, it is clear that the power efficiency is greatly increased to about 16% when the thin-film solar has at least three germanium layers. Further, FIG. 5 also shows a diagram indicating that the voltage-current characteristic of the thin-film solar cell of the present invention having three germanium layers, each of which has a thickness of 3 nm.

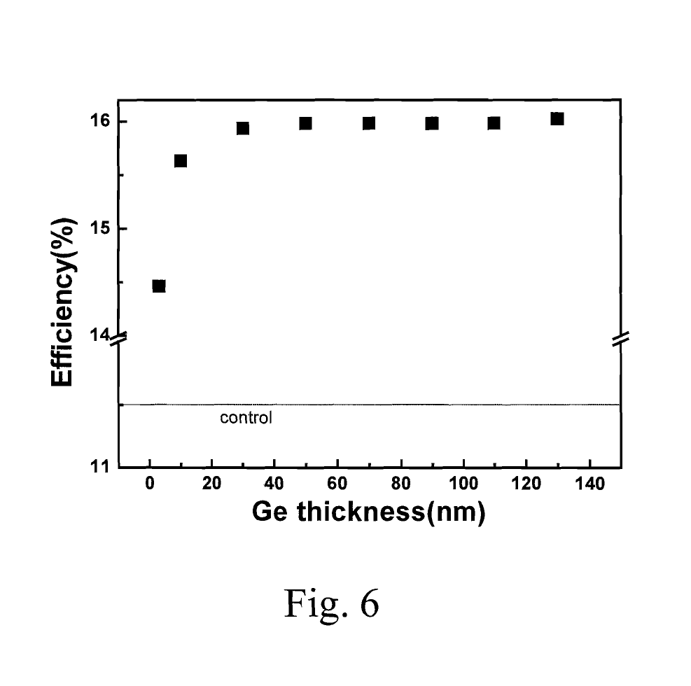

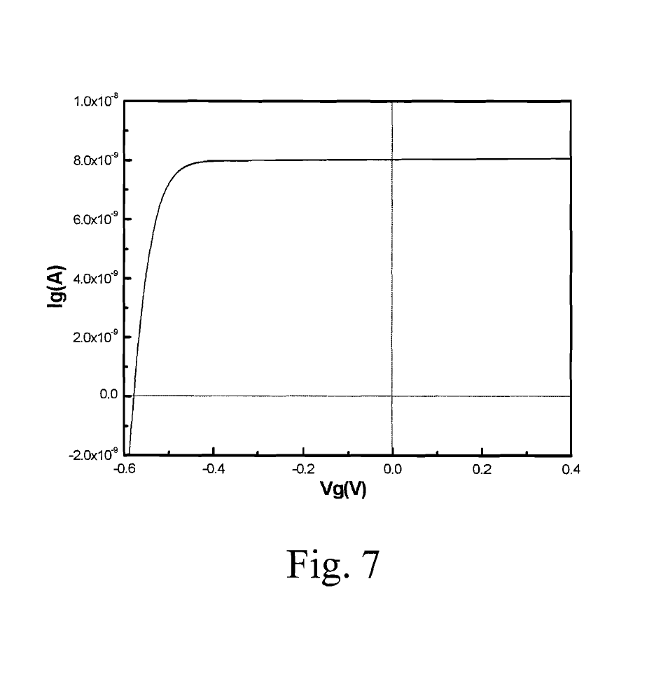

Moreover, in a further preferred embodiment of the present invention, the thickness of the germanium layer contained in the thin-film solar cell can also be used as a parameter to enhance the power efficiency of the thin-film solar cell. Please refer to FIG. 6, which shows a diagram indicating that the thickness of the germanium layer contained in the thin-film solar cell of the present invention is effective to the power efficiency of the solar cell. From the data shown in FIG. 6, it is clear that the power efficiency is greatly increased to about 16% when the thin-film solar has a thickness more than 30 nm. Further, FIG. 7 also shows a diagram indicating that the voltage-current characteristic of the thin-film solar cell of the present invention including a germanium layer having a thickness of 30 nm.

Based on the above, it is clear that the power efficiency of the thin-film solar cell of the present invention can be increased to about 16% by adjusting the number of the germanium layers or the thickness of the germanium layer of the multi-layered structure of the thin-film solar cell, which is better than conventional thin-film solar cell usually having a power efficiency of about 12%. Further, the method for manufacturing the thin-film solar cell of the present invention is totally compatible with the process used for manufacturing the conventional thin-film solar cell. Accordingly, the manufacturing process for the thin-film solar cell having the hetero-junctions of silicon-germanium-silicon is much simpler, and the necessary materials and its relevant fabrication cost for such thin-film solar cell structure are remarkably reduced

While the invention has been described in terms of what are presently considered to be the most practical and preferred embodiments, it is to be understood that the invention need not be limited to the disclosed embodiment. On the contrary, it is intended to cover various modifications and similar arrangements included within the spirit and scope of the appended claims, which are to be accorded with the broadest interpretation so as to encompass all such modifications and similar structures. Therefore, the above description and illustration should not be taken as limiting the scope of the present invention which is defined by the appended claims.

What is claimed is:

1. A thin-film solar cell, comprising:
a substrate having a first surface;
a multi-layered structure disposed on the first surface, wherein the multi-layered structure is made of different semiconductor materials selected from elements of the same group;
a first electrode layer disposed on the multi-layered structure, wherein the first electrode layer is a ring shaped structure having a vacant space formed thereon;
an insulation layer disposed on the vacant space; and
a second electrode layer disposed on the insulation layer and insulated from the first electrode layer.

2. A thin-film solar cell according to claim 1, wherein the substrate is one selected from a group consisting of a relatively low quality silicon substrate, a glass substrate and other relatively cheap substrates.

3. A thin-film solar cell according to claim 1, wherein the multi-layered structure is made of the different semiconductor materials of IV group elements.

4. A thin-film solar cell according to claim 1, wherein the multi-layered structure comprises:
a first silicon layer;
a hetero-structure layer disposed on the first silicon layer; and
a second silicon layer disposed on the hetero-structure layer, wherein the hetero-structure layer is one of a germanium layer and a silicon-germanium layer.

5. A thin-film solar cell according to claim 4, wherein the hetero-structure layer has a thickness ranged from 3 nm to 30 nm.

6. A thin-film solar cell according to claim 1, wherein the multi-layered structure one of a Si/Ge/Si quantum well and a Si/Ge/Si quantum dot.

7. A thin-film solar cell according to claim 1, wherein the multi-layered structure one of a Si/SiGe/Si quantum well and a Si/SiGe/Si quantum dot.

8. A thin-film solar cell according to claim 1, wherein the insulation layer is made of a dielectric material having a dielectric constant lager than 3.

9. A thin-film solar cell according to claim 8, wherein the dielectric material is one of a group consisting of a silicon dioxide, a silicon nitride, and a hafnium oxide.

10. A thin-film solar cell, comprising:
a substrate having a first surface;
a first electrode layer disposed on the first surface;
a multi-layered structure disposed on the first electrode layer, wherein the multi-layered structure has a hetero junction structure formed by different semiconductor materials selected from elements of the same group; and
an insulation layer disposed on the multi-layered structure.

11. A method for fabricating a thin-film solar cell, the thin-film solar cell having a hetero-junction structure formed by different semiconductor materials selected from elements of the same group, the method comprising:
(a) providing a silicon substrate having a first surface and a second surface;
(b) providing a semiconductor layer made of IV group elements on the first surface;
(c) providing a silicon layer on the semiconductor layer, so as to form a hetero-junction structure;
(d) implanting hydrogen ions (H⁺) into the hetero-junction structure, so that an implanted hydrogen ions interface is formed within the silicon substrate; and
(e) providing a carrier substrate bonding to the silicon layer and then heating the hetero-junction structure having the implanted hydrogen ions interface, so that the silicon substrate is exfoliated along the hydrogen ions interface and a exfoliated surface of the silicon substrate is formed.

12. A method according to claim 11, further comprising a step of (e′) doping the hetero-junction structure after the step (e).

13. A method according to claim 11, further comprising a step of (e″) planarizing the exfoliated surface after the step (e).

14. A method according to claim 13, further comprising following steps after the step (e″):
(f) providing a first electrode layer on the exfoliated surface;
(g) forming a vacant space on the central portion of first electrode layer, so as to make the first electrode as a ring shaped structure, wherein an exposed portion of the exfoliated surface is revealed in the vacant space;
(h) providing an insulation layer on the exposed portion of the exfoliated surface; and
(i) providing a second electrode layer on the insulation layer, through which the first electrode layer is insulated from the second electrode layer.

15. A method according to claim 11, wherein the step (e) further comprises:
(e1) providing the carrier substrate having thereon a first electrode layer; and
(e2) bonding the first electrode layer into the silicon layer.

16. A method according to claim 15, further comprising a step of (f) providing a second electrode layer on the exfoliated surface after the step (e).

17. A method according to claim 11, wherein the semiconductor layer and the silicon layer are formed by one of an epitaxial process and a wafer bonding process.

18. A method according to claim 17, wherein the epitaxial process is performed by one selected from a group consisting of a molecular beam epitaxy (MBE) system, a plasma enhanced chemical vapor deposition (PECVD) system, and a ultra high vacuum chemical vapor deposition (UHVCVD) system.

19. A method according to claim 11, wherein the step (b) and the step (c) are alternately and repeatedly performed, so that a multi-layered structure having multiple hetero-junctions is formed.
